(19) United States
(12) Patent Application Publication
(10) Pub. No.: US 2026/0012155 A1
(43) Pub. Date: Jan. 8, 2026

(54) BULK ACOUSTIC WAVE RESONATOR UTILIZING OVERTONE MODES

(71) Applicant: SKYWORKS GLOBAL PTE. LTD., Singapore (SG)

(72) Inventors: Benjamin Paul Abbott, Irvine, CA (US); Alexandre Augusto Shirakawa, Cardiff by the Sea, CA (US); David Albert Feld, Los Altos, CA (US); Kwang Jae Shin, Yongin-si (KR); Jun Yu, Irvine, CA (US)

(21) Appl. No.: 19/258,314

(22) Filed: Jul. 2, 2025

Related U.S. Application Data
(60) Provisional application No. 63/667,371, filed on Jul. 3, 2024.

(51) Int. Cl. H03H 9/02; H03H 9/17; H03H 9/56

(52) U.S. Cl. CPC H03H 9/0207; H03H 9/02015; H03H 9/02102; H03H 9/174; H03H 9/568

(57) ABSTRACT

Aspects and embodiments disclosed herein include a bulk acoustic wave resonator including a material layer stack located in a central active region of the bulk acoustic wave resonator, the material layer stack comprising a bottom electrode, a first piezoelectric material layer disposed on an upper surface of the bottom electrode, a second piezoelectric material layer disposed on the first piezoelectric material layer, a polarity of the second piezoelectric material layer being opposite a polarity of the first piezoelectric material layer, an interposer layer disposed between the first piezoelectric material layer and the second piezoelectric material layer, and a top electrode having a lower surface disposed on an upper surface of the upper piezoelectric material layer.

### CROSS-REFERENCE TO RELATED APPLICATIONS

This application claims priority under 35 U.S.C. § 119 (e) to U.S. Provisional Patent Application Ser. No. 63/667,371, titled “BULK ACOUSTIC WAVE RESONATOR UTILIZING OVERTONE MODES,” filed Jul. 3, 2024, the entire content of which is incorporated herein by reference for all purposes.

### TECHNICAL FIELD

Embodiments of this disclosure relate to bulk acoustic wave resonators and to acoustic wave filters including same in which the bulk acoustic wave resonators utilize an overtone of vibration of their piezoelectric material films to generate the main acoustic waves used by the resonators.

### DESCRIPTION OF RELATED TECHNOLOGY

Acoustic wave filters can filter radio frequency signals. An acoustic wave filter can include a plurality of resonators arranged to filter a radio frequency signal. The resonators can be arranged as a ladder circuit. Example acoustic wave filters include surface acoustic wave (SAW) filters, bulk acoustic wave (BAW) filters, and Lamb wave resonator filters. A film bulk acoustic wave resonator filter is an example of a BAW filter. A solidly mounted resonator (SMR) filter is another example of a BAW filter.

Acoustic wave filters can be implemented in radio frequency electronic systems. For instance, filters in a radio frequency front end of a mobile phone can include acoustic wave filters. Two acoustic wave filters can be arranged as a duplexer.

### SUMMARY

In accordance with one aspect, there is provided a bulk acoustic wave resonator including a material layer stack located in a central active region of the bulk acoustic wave resonator, the material layer stack comprising a bottom electrode, a first piezoelectric material layer disposed on an upper surface of the bottom electrode, and a second piezoelectric material layer disposed on the first piezoelectric material layer. A polarity of the second piezoelectric material layer is opposite a polarity of the first piezoelectric material layer. An interposer layer is disposed between the first piezoelectric material layer and the second piezoelectric material layer. The bulk acoustic wave resonator further includes a top electrode having a lower surface disposed on an upper surface of the second piezoelectric material layer.

In some embodiments, the interposer layer is formed of ruthenium.

In some embodiments, the interposer layer has a thickness sufficient to cause the bulk acoustic wave resonator to generate a second overtone vibrational mode.

In some embodiments, the bulk acoustic wave resonator further comprises a third piezoelectric material layer disposed between the second piezoelectric material layer and the top electrode.

In some embodiments, the third piezoelectric material layer has a polarity opposite to the polarity of the second piezoelectric material layer.

In some embodiments, the bulk acoustic wave resonator further comprises a second interposer layer disposed between the second piezoelectric material layer and the third piezoelectric material layer.

In some embodiments, at least one of the first, second, or third piezoelectric material layers has a different thickness than at least one other of the first, second, or third piezoelectric material layers.

In some embodiments, the second piezoelectric material layer is thicker than the first piezoelectric material layer and the third piezoelectric material layer.

In some embodiments, the bulk acoustic wave resonator further comprises a fourth piezoelectric material layer disposed between the third piezoelectric material layer and the top electrode.

In some embodiments, the fourth piezoelectric material layer has a polarity opposite to the polarity of the third piezoelectric material layer.

In some embodiments, the bulk acoustic wave resonator further comprises a third interposer layer disposed between the third piezoelectric material layer and the fourth piezoelectric material layer.

In some embodiments, the bulk acoustic wave resonator further comprises a temperature compensation layer disposed over the top electrode.

In some embodiments, the temperature compensation layer has a thickness sufficient to cause the bulk acoustic wave resonator to generate a second overtone vibrational mode.

In some embodiments, one of the bottom electrode or the top electrode has a thickness sufficient to cause the bulk acoustic wave resonator to generate a second overtone vibrational mode.

In some embodiments, the first piezoelectric material layer and the second piezoelectric material layer are each Sc-doped AlN.

In some embodiments, the first piezoelectric material layer and the second piezoelectric material layer include at least 15 atomic percent Sc.

In some embodiments, the top electrode includes an upper layer and a lower layer, and a temperature compensation layer is disposed between the upper layer and the lower layer.

In some embodiments, the bulk acoustic wave resonator is configured as a film bulk acoustic wave resonator.

In some embodiments, the bulk acoustic wave resonator is included in a radio frequency filter.

In some embodiments, the radio frequency filter is included in a radio frequency module. In some embodiments, the radio frequency module is included in a radio frequency device.

### BRIEF DESCRIPTION OF THE DRAWINGS

Embodiments of this disclosure will now be described, by way of non-limiting example, with reference to the accompanying drawings.

FIG. 1 is a cross-sectional view of an example of film bulk acoustic wave resonator;

FIG. 2 is a cross-sectional view of an example of a solidly mounted resonator;

FIG. 3 illustrates thickness of material layers in examples of BAW resonators operating at a fundamental mode;

FIG. 4 illustrates the stress fields within a piezoelectric material film and the convention used herein for referring to the fundamental vibrational mode and overtone vibrational modes;

FIG. 5 illustrates stacks of layers in the active areas of examples of BAW resonators that may operate at the fundamental vibrational mode and at first, second, and third overtones;

FIGS. 6A-6D illustrate material layer stacks for BAW resonators and their materials and thicknesses each having a resonant frequency at about 13 GHz but operating at the fundamental mode and at different overtones as well as charts of simulated admittance parameters of the BAW resonators. The Y axes in these charts as well as other charts of admittance parameters herein are labelled “Capacity (pF)” which is admittance/(2π*frequency)

FIG. 7 illustrates stacks of layers in the active areas of further examples of BAW resonators that may operate at the fundamental vibrational mode and at first, second, and third overtones;

FIGS. 8A-8D illustrate material layer stacks for further examples if BAW resonators and their materials and thicknesses each having a resonant frequency at about 13 GHz but operating at the fundamental mode and at different overtones as well as charts of simulated admittance parameters of the BAW resonators;

FIG. 9 is a table illustrating simulated operating parameters of BAW resonators having the material layer stacks illustrated in FIGS. 6A-6D and 8A-8D;

FIG. 10A illustrates a material layer stack of an example of a BAW resonator configured to operate at the second overtone and including a temperature compensation layer;

FIG. 10B illustrates a material layer stack of another example of a BAW resonator configured to operate at the second overtone;

FIG. 11 illustrates the material layer stack of a BAW resonator operating at the fundamental tone as compared to material layer stacks of BAW resonators operating at the first overtone, high odd modes, and high even modes;

FIG. 12 compares material layer stacks of two BAW resonators operating at the first overtone and including passive layers and associated simulated performance metrics;

FIG. 13A illustrates examples of material layer stacks for BAW resonators operating at the first overtone where the piezoelectric material layers are doped with different amounts of Sc;

FIG. 13B illustrates simulated performance metrics for BAW resonators having the material layer stacks illustrated in FIG. 13A;

FIGS. 13C-13G illustrate Capacity curves for examples of BAW resonators as disclosed herein with different amounts of Sc doping;

FIGS. 14A-14C illustrate what is meant by the term “high even overtone” resonators herein;

FIGS. 15A and 15B illustrate a comparison between examples of material layer stacks for a first even overtone mode resonator and a third even overtone mode resonator;

FIG. 15C illustrates simulated performance metrics for BAW resonators having the material layer stacks shown in FIGS. 15A and 15B;

FIGS. 15D and 15E illustrates simulated admittance curves for BAW resonators having the material layer stacks shown in FIGS. 15A and 15B;

FIG. 16A illustrates examples of material layer stacks for first even overtone BAW resonators including a SiO₂ temperature compensation layer above the top electrode and varying amounts of Sc doping in the piezoelectric material layers;

FIG. 16B illustrates simulated performance metrics for BAW resonators having the material layer stacks shown in FIG. 16A;

FIGS. 16C-16F illustrate simulated admittance curves for BAW resonators having the material layer stacks shown in FIG. 16A;

FIGS. 17A and 17B illustrate material layer stacks for first overtone BAW resonators operating at the same frequency with a temperature compensation layer above the top electrode or between upper and lower top electrode layers, respectively;

FIG. 17C illustrates simulated performance parameters for BAW resonators having the material layer stacks shown in FIGS. 17A and 17B;

FIG. 18A is a comparison of simulated series resistance of BAW resonators operating at the fundamental mode, a high even mode, and a high odd mode at the same operating frequency and with varying Sc doping of the piezoelectric material layers;

FIG. 18B is a comparison of simulated average piezoelectric material layer thickness of BAW resonators operating at the fundamental mode, a high even mode, and a high odd mode at the same operating frequency and with varying Sc doping of the piezoelectric material layers;

FIGS. 18C and 18D are comparisons of simulated bottom electrode and top electrode thicknesses, respectively, of BAW resonators operating at the fundamental mode, a high even mode, and a high odd mode at the same operating frequency and with varying Sc doping of the piezoelectric material layers;

FIG. 19 illustrates a simplified schematic diagram of a ladder filter that may be formed from resonators as disclosed herein;

FIG. 20 illustrates an embodiment of an electronics module;

FIG. 21 illustrates an example of a front-end module which may be used in an electronic device; and

FIG. 22 illustrates an example of an electronic device.

### DETAILED DESCRIPTION

The following description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

Film bulk acoustic wave resonators are a form of bulk acoustic wave resonator that generally includes a film of piezoelectric material sandwiched between a top and a bottom electrode and suspended over a cavity that allows for the film of piezoelectric material to vibrate. A signal applied across the top and bottom electrodes causes an acoustic wave to be generated in and travel through the film of piezoelectric material. A film bulk acoustic wave resonator exhibits a frequency response to applied signals with a resonance peak determined in part by a thickness of the film of piezoelectric material. Ideally, the only acoustic wave that would be generated in a film bulk acoustic wave resonator is a main acoustic wave that would travel through the film of piezoelectric material in a direction perpendicular to layers of conducting material forming the top and bottom electrodes. The piezoelectric material of a film bulk acoustic wave resonator, however, typically has a non-zero Poisson's ratio. Compression and relaxation of the piezoelectric material associated with passage of the main acoustic wave may thus cause compression and relaxation of the piezoelectric material in a direction perpendicular to the direction of propagation of the main acoustic wave. The compression and relaxation of the piezoelectric material in the direction perpendicular to the direction of propagation of the main acoustic wave may generate transverse acoustic waves that travel perpendicular to the main acoustic wave (parallel to the surfaces of the electrode films) through the piezoelectric material. The transverse acoustic waves may be reflected back into an area in which the main acoustic wave propagates and may induce spurious acoustic waves travelling in the same direction as the main acoustic wave. These spurious acoustic waves may degrade the frequency response of the film bulk acoustic wave resonator from what is expected or from what is intended and are generally considered undesirable.

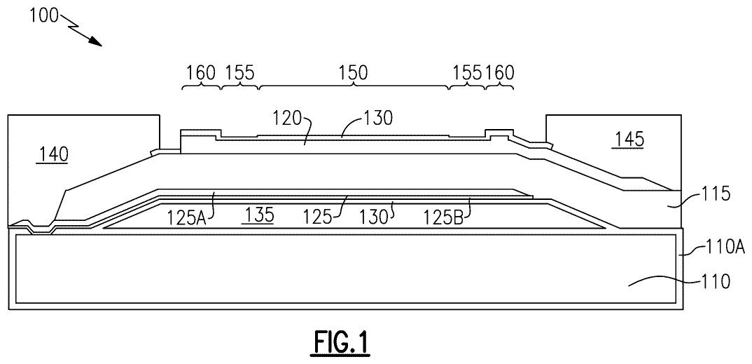

FIG. 1 is cross-sectional view of an example of a film bulk acoustic wave resonator, indicated generally at 100. The film bulk acoustic wave resonator 100 is disposed on a substrate 110, for example, a silicon substrate that may include a dielectric surface layer 110A of, for example, silicon dioxide. The film bulk acoustic wave resonator 100 includes a layer or film of piezoelectric material 115, for example, aluminum nitride (AlN) or scandium-doped aluminum nitride (AlₓSc₁₋ₓN, referred to herein without subscripts as AlScN). A top electrode 120 (often abbreviated MTE for Metal Top Electrode) is disposed on top of a portion of the layer or film of piezoelectric material 115 and a bottom electrode 125 (often abbreviated MBE for Metal Bottom Electrode) is disposed on the bottom of a portion of the layer or film of piezoelectric material 115. The top electrode 120 may be formed of, for example, ruthenium (Ru). The bottom electrode 125 may include a layer 125A of Ru disposed in contact with the bottom of the portion of the layer or film of piezoelectric material 115 and a layer 125B of titanium (Ti) disposed on a lower side of the layer 125A of Ru opposite a side of the layer 125A of Ru in contact with the bottom of the portion of the layer or film of piezoelectric material 115. Each of the top electrode 120 and the bottom electrode 125 may be covered with a layer of dielectric material 130, for example, silicon dioxide. A cavity 135 is defined beneath the layer of dielectric material 130 covering the bottom electrode 125 and the surface layer 110A of the substrate 110. A bottom electrical contact 140 formed of, for example, copper may make electrical connection with the bottom electrode 125 and a top electrical contact 145 formed of, for example, copper may make electrical connection with the top electrode 120.

The film bulk acoustic wave resonator 100 may include a central region 150 (also referred to as a central active region) including a main active domain in the layer or film of piezoelectric material 115 in which a main acoustic wave is excited during operation. The central region may have a width of, for example, between about 20 μm and about 100 μm. A recessed frame region or regions 155 may bound and define the lateral extent of the central region 150. The recessed frame regions may have a width of, for example, about 1 μm. The recessed frame region(s) 155 may be defined by areas that have a thinner layer of dielectric material 130 on top of the top electrode 120 than in the central region 150. The dielectric material layer 130 in the recessed frame region(s) 155 may be from about 10 nm to about 100 nm thinner than the dielectric material layer 130 in the central region 150. The difference in thickness of the dielectric material in the recessed frame region(s) 155 vs. in the central region 150 may cause the resonant frequency of the device in the recessed frame region(s) 155 to be between about 5 MHz to about 50 MHz higher than the resonant frequency of the device in the central region 150. In some embodiments, the thickness of the dielectric material layer 130 in the central region 150 may be about 200 nm to about 300 nm and the thickness of the dielectric material layer 130 in the recessed frame region(s) 155 may be about 100 nm. The dielectric film 300 in the recessed frame region(s) 155 is typically etched during manufacturing to achieve a desired difference in acoustic velocity between the central region 150 and the recessed frame region(s) 155. Accordingly, the dielectric film 300 initially deposited in both the central region 150 and recessed frame region(s) 155 is deposited with a sufficient thickness that allows for etching of sufficient dielectric film 300 in the recessed frame region(s) 155 to achieve a desired difference in thickness of the dielectric film 300 in the central region 150 and recessed frame region(s) 155 to achieve a desired acoustic velocity difference between these regions.

A raised frame region or regions 160 may be defined on an opposite side of the recessed frame region(s) 155 from the central region 150 and may directly abut the outside edge(s) of the recessed frame region(s) 155. The raised frame regions may have widths of, for example, about 1 μm. The raised frame region(s) 160 may be defined by areas where the top electrode 120 is thicker than in the central region 150 and in the recessed frame region(s) 155. The top electrode 120 may have the same thickness in the central region 150 and in the recessed frame region(s) 155 but a greater thickness in the raised frame region(s) 160. The top electrode 120 may be between about 50 nm and about 500 nm thicker in the raised frame region(s) 160 than in the central region 150 and/or in the recessed frame region(s) 155. In some embodiments the thickness of the top electrode in the central region may be between 50 and 500 nm.

The recessed frame region(s) 155 and the raised frame region(s) 160 may contribute to dissipation or scattering of transverse acoustic waves generated in the film bulk acoustic wave resonator 100 during operation and/or may reflect transverse waves propagating outside of the recessed frame region(s) 155 and the raised frame region(s) 160 and prevent these transverse acoustic waves from entering the central region and inducing spurious signals in the main active domain region of the film bulk acoustic wave resonator. Without being bound to a particular theory, it is believed that due to the thinner layer of dielectric material 130 on top of the top electrode 120 in the recessed frame region(s) 155, the recessed frame region(s) 155 may exhibit a higher velocity of propagation of acoustic waves than the central region 150. Conversely, due to the increased thickness and mass of the top electrode 120 in the raised frame region(s) 160, the raised frame regions(s) 160 may exhibit a lower velocity of propagation of acoustic waves than the central region 150 and a lower velocity of propagation of acoustic waves than the recessed frame region(s) 155. The discontinuity in acoustic wave velocity between the recessed frame region(s) 155 and the raised frame region(s) 160 creates a barrier that scatters, suppresses, and/or reflects transverse acoustic waves.

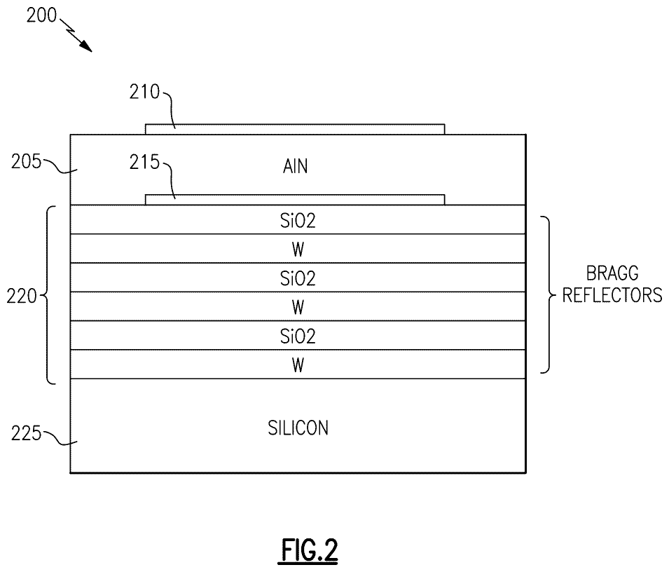

Another form of BAW resonator is a solidly mounted resonator (SMR). An example of an SMR is illustrated generally at 200 in FIG. 2. As illustrated, the SMR 200 includes a piezoelectric material layer 205, an upper electrode 210 (MTE) on the piezoelectric material layer 205, and a lower electrode 215 (MBE) on a lower surface of the piezoelectric material layer 205. The piezoelectric material layer 205 can be an AlN or AlScN layer. In other instances, the piezoelectric material layer 205 can be formed of any other suitable piezoelectric material. The lower electrode 215 can be grounded in certain instances. In some other instances, the lower electrode 215 can be floating. Bragg reflectors 220 are disposed between the lower electrode 215 and a semiconductor substrate 225. The semiconductor substrate 225 can be a silicon substrate. Any suitable Bragg reflectors can be implemented. For example, the Bragg reflectors can be SiO₂/W.

It should be appreciated that the BAW resonators and piezoelectric material layers illustrated in the figures are illustrated in a highly simplified form. The relative dimensions of the different features are not shown to scale. Further, typical BAW resonators may include additional features or layers not illustrated.

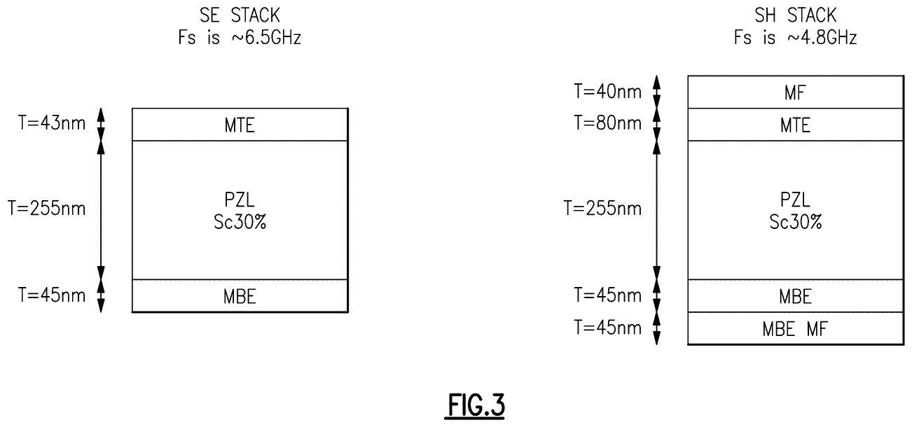

As noted above, the operating frequency of a BAW resonator is at least in part dependent on the thickness of the piezoelectric material film within the BAW resonator; generally, the thinner the piezoelectric material film the higher the operating frequency. The market is continuing to demand wireless devices operating at higher and higher frequencies. Piezoelectric material layers in BAW resonators, however, can only be made so thin before manufacturing repeatability, operational reliability, ruggedness, and quality factor begin to suffer. In the past, most BAW resonators utilized an acoustic wave that was generated at the fundamental tone or first harmonic frequency of vibration of their piezoelectric material layers. As illustrated in FIG. 3, to achieve an admittance response for a series arm resonator in a ladder filter used, for example, for the Wi-Fi 7 band, with a first harmonic or fundamental mode resonance frequency of about 6.5 GHZ, the piezoelectric film layer has a thickness of 255 nm and the top and bottom electrode thicknesses are 43 nm and 45 nm, respectively (the “SE Stack” in FIG. 3). A corresponding shunt resonator may have the same piezoelectric material layer thickness of 255 nm, but thicker upper and lower electrode thicknesses—80 nm and 40 nm, respectively—as well as upper and lower mass loading films MF and MBF to achieve an admittance response with a first harmonic or fundamental mode resonance frequency of about 4.8 GHz. These piezoelectric material layer thicknesses are very thin and may result in the resonators being less rugged than desirable. Additionally, the electrode layers are so thin that electrical resistance may be higher than desired.

It has been discovered that it is possible to increase the total thickness of the piezoelectric material film and of the electrodes of a BAW resonator (either a film bulk acoustic wave resonator or solidly mounted resonator) while still operating at a desired high frequency by designing the BAW resonator to utilize the first overtone or second harmonic, or higher overtones or harmonics, of the piezoelectric material film stack as the main acoustic wave of the resonator. The first overtone or second harmonic is typically about twice the frequency of the fundamental mode or first harmonic, subject to some reduction in frequency due to the mass of the electrodes and other material layers deposited on or below the piezoelectric material layer of the resonator. Utilizing higher harmonics or overtones rather than the first harmonic of BAW resonators in a RF filter may provide for the filter to operate at higher frequencies without having to reduce the thickness of the piezoelectric material films of the resonators to thicknesses that might cause manufacturing repeatability or operational reliability issues.

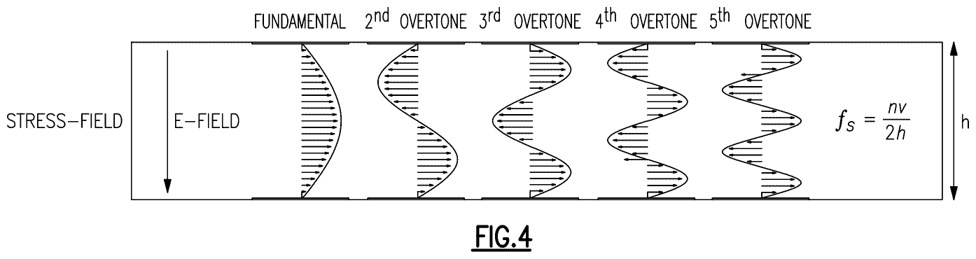

FIG. 4 illustrates the stress fields within a piezoelectric material film with thickness h and the conventions used herein for referring to the fundamental vibrational mode and overtone vibrational modes. The fundamental resonance frequency f_{R} of a BAW resonator stack refers to the lowest resonant frequency at which the resonator exhibits a significant response. In the context of BAW filters, the fundamental frequency corresponds to the primary vibrational mode of the piezoelectric material within the stack. In a single piezoelectric layer stack the fundamental frequency f_{R} is defined by:

$${f}_{R} = v / 2 h$$

with v being the velocity of the waves in the piezoelectric material and h being the thickness of the piezoelectric material layer.

Overtones refer to higher harmonic resonances in the BAW filter stack. Each overtone shown in FIG. 4 corresponds to a higher-order vibrational mode of the piezoelectric material layer. The presence of overtones results in multiple resonant frequencies within the BAW resonator stack. The spacing between these resonant frequencies is influenced by factors such as the thickness of the piezoelectric material layer and the specific design of the resonator.

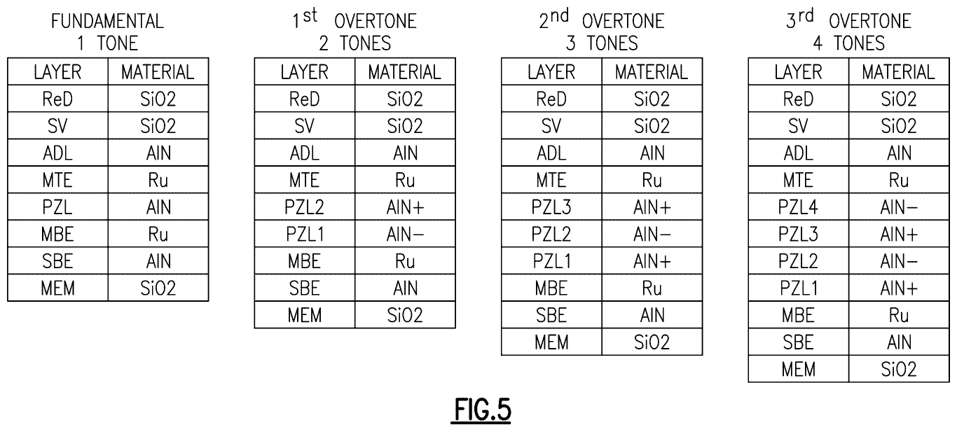

The stack of layers in the active area of a BAW resonator operating on the nth tone may be constructed by including n piezoelectric material layers (PZL) with alternating polarity, where polarity refers to the crystallographic orientation of the PZL in the thickness direction. FIG. 5 illustrates examples of stacks of layers in the active areas of examples of BAW resonators (also referred to herein as simply “material layer stacks”) that may operate at the fundamental vibrational mode and at first, second, and third overtones. The examples in FIG. 5 are more detailed than the stack of layers in the active area of the BAW resonator illustrated in FIG. 1.

The layer stacks in the examples of FIG. 5 include a metal top electrode (MTE) and metal bottom electrode (MBE) sandwiching one or more layers of piezoelectric material (PZL) which may have different polarities (AlN+ and AlN—) and also an adhesion layer (ADL), a passivation/trim layer (SV), a recess depth layer (ReD), a seed bottom layer (SBE), and an etch stop layer for sacrificial layer etch (MEM).

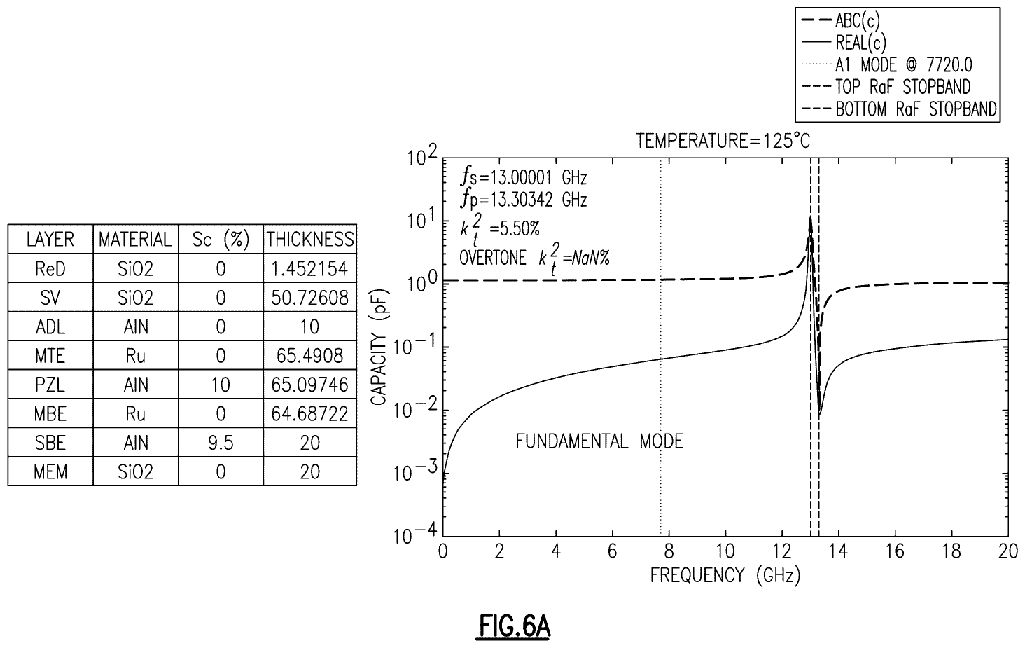

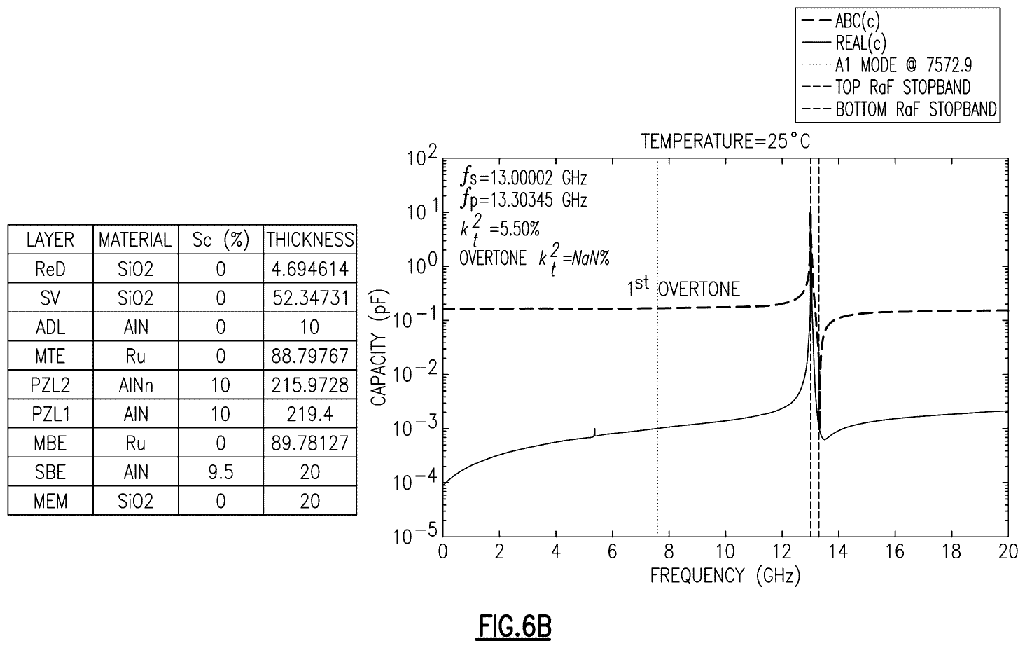

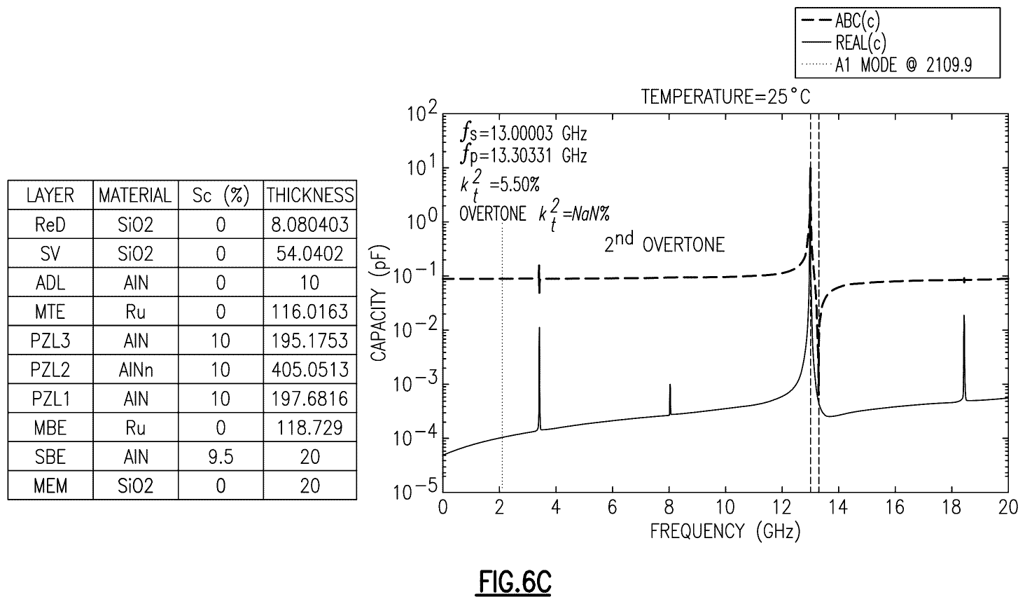

FIGS. 6A-6D illustrate material layer stacks for BAW resonators and their materials and thicknesses (expressed in nm) each having a resonant frequency at about 13 GHz but operating at the fundamental mode and at different overtones. It can be observed that the piezoelectric material layer, or combination of the piezoelectric material sublayers with different polarities (AlN and AlNn), as well as the electrode layers, increase in thickness with each higher overtone, which may make resonators operating at higher overtones more rugged than a resonator operating at the fundamental mode for a given operating frequency as well as exhibiting a lower electrode resistance.

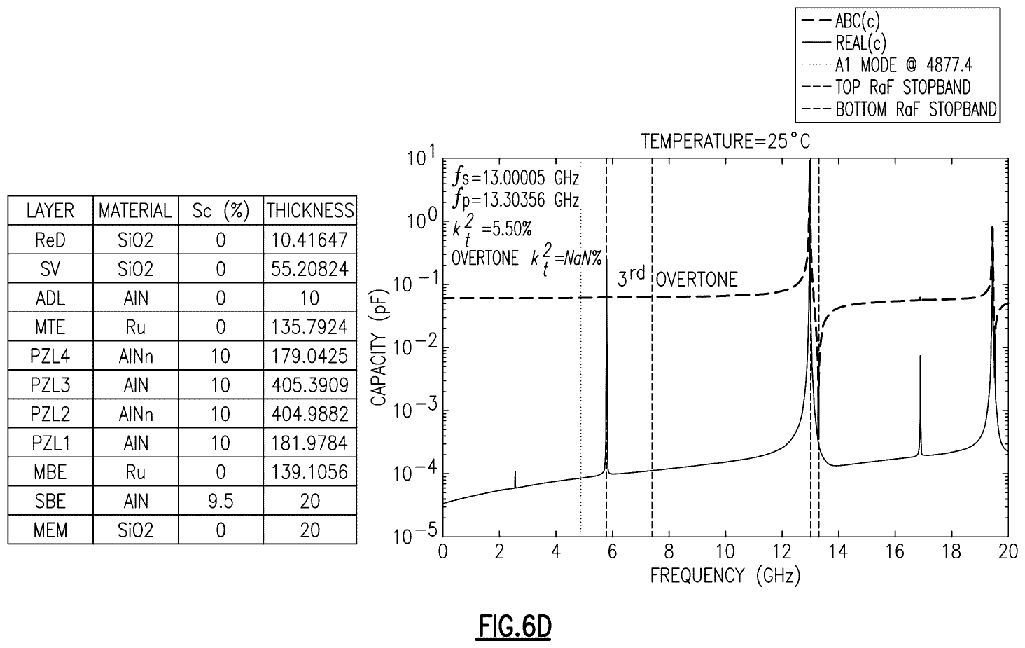

For the purpose of inverting/flipping the polarity of piezoelectric material layers in a BAW material layer stack, using an interposer layer that promotes the desired polarity is advantageous. In the examples in FIG. 7, this is represented by thin MME/interposer Ru layers.

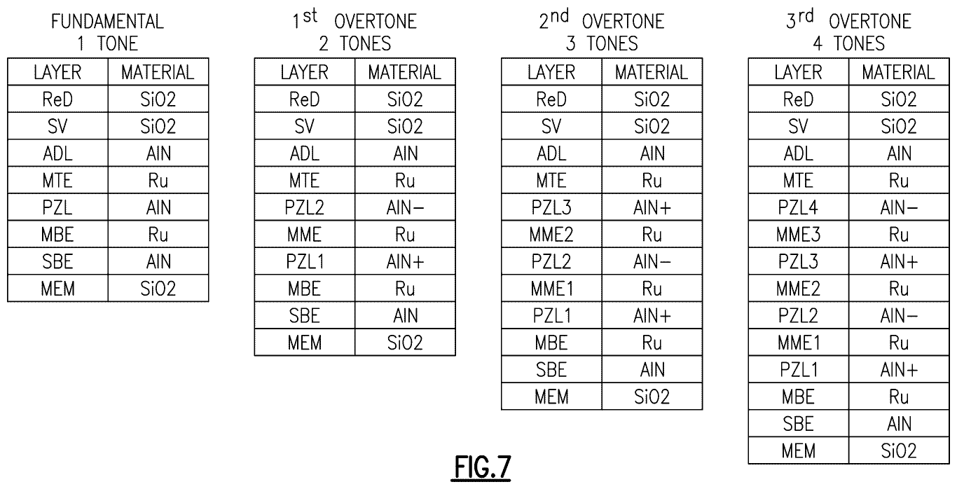

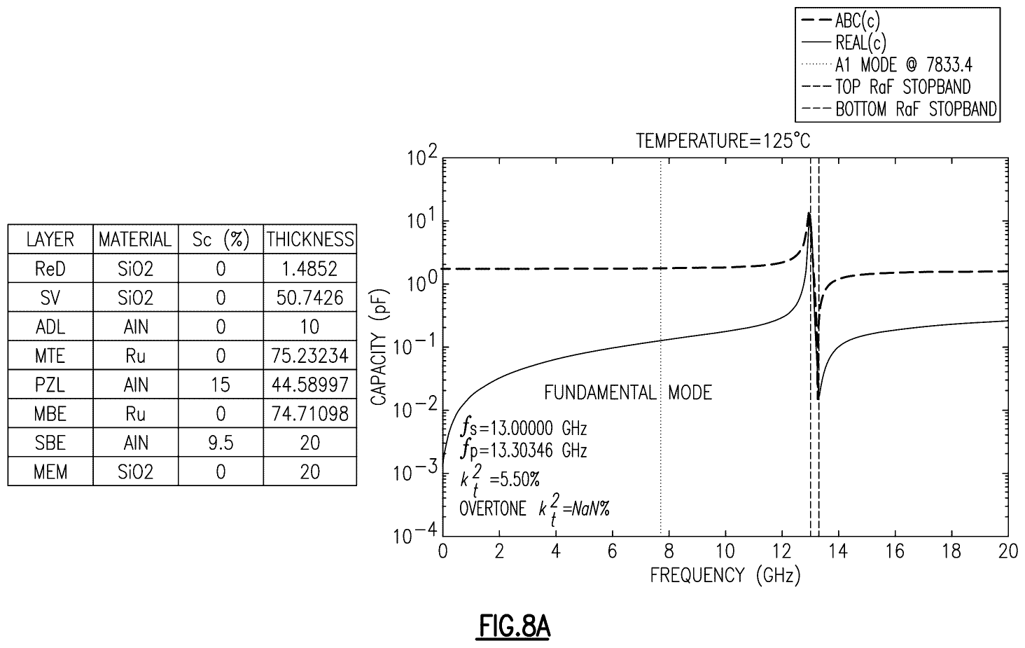

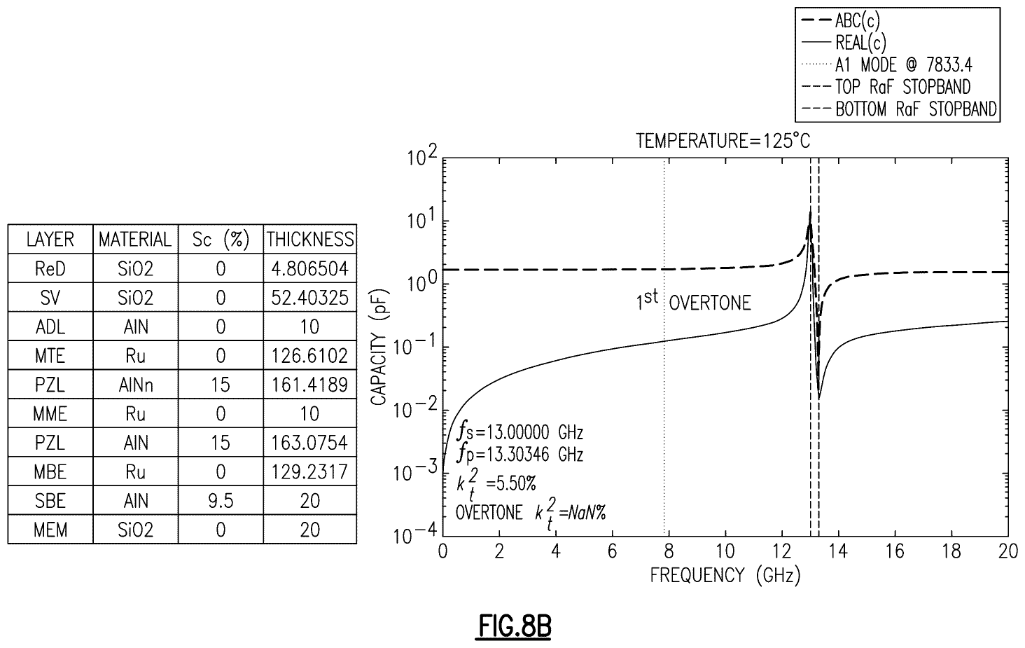

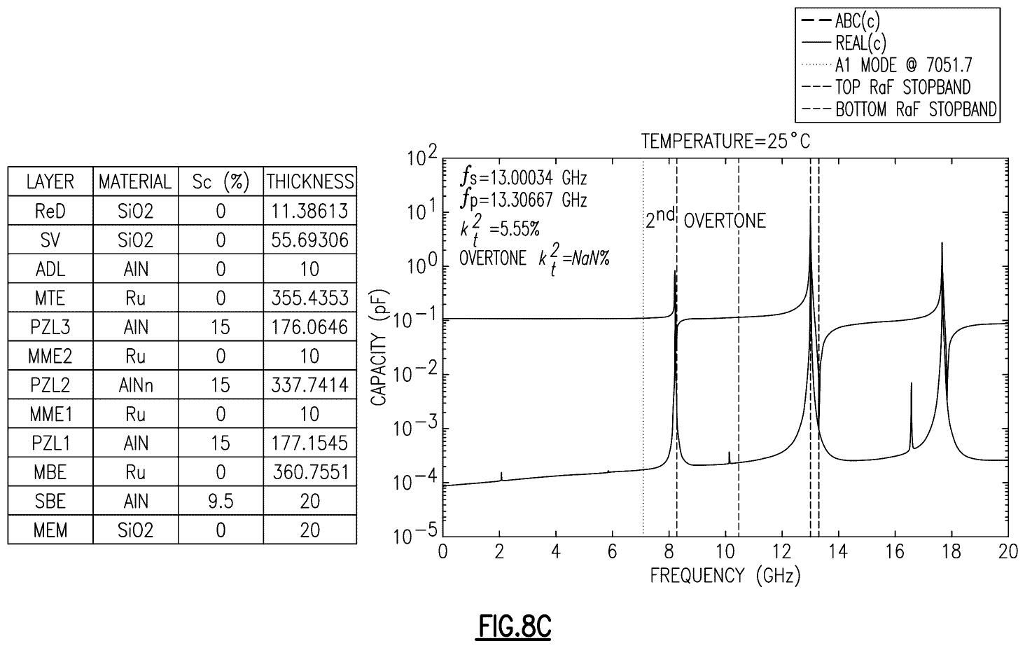

FIGS. 8A-8D illustrate material layer stacks for BAW resonators and their materials and thicknesses (expressed in nm) each having a resonant frequency at about 13 GHz but operating at the fundamental mode and at different overtones. The material layer stacks in FIGS. 8A-8D are similar to those in FIGS. 6A-6D except the material layer stacks in FIGS. 8A-8D include thin MME interposer layers between piezoelectric material films with different polarities.

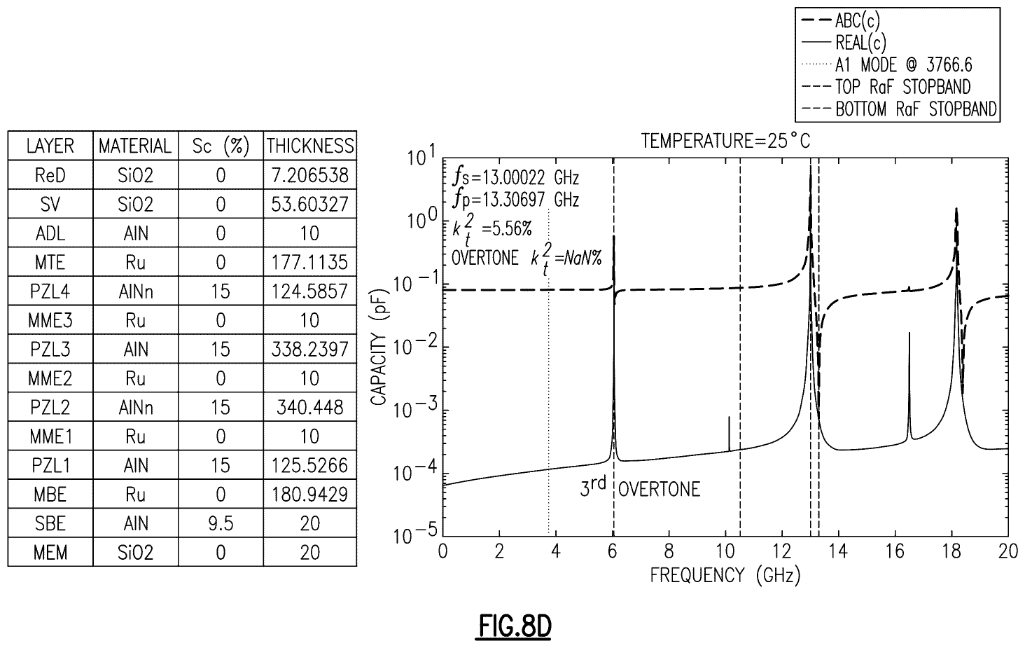

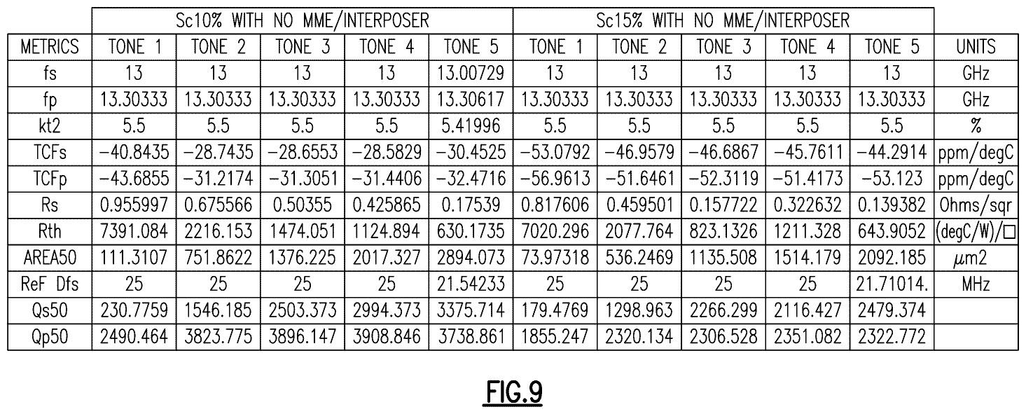

FIG. 9 is a table illustrating simulated operating parameters of BAW resonators having the material layer stacks illustrated in FIGS. 6A-6D and 8A-8D. From FIG. 9 it can be seen that as resonators are configured to operate at higher tones for the same operating frequency, the electrode thicknesses may be increased, leading to reduced electrode resistance.

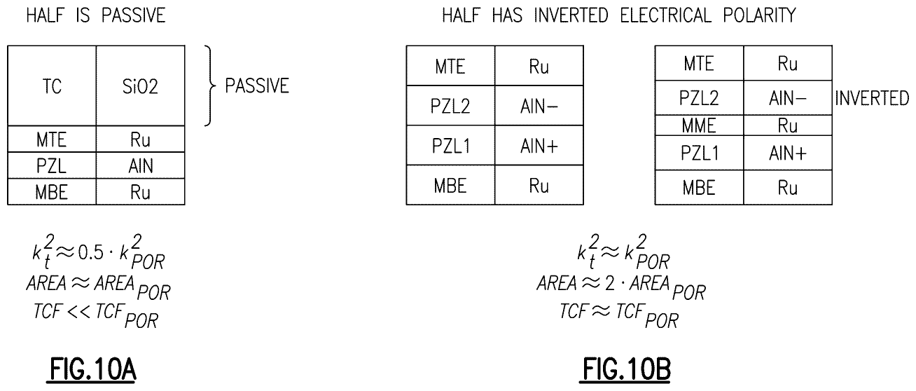

In some embodiments, BAW material layer stacks for BAW resonators operating at the second overtone may include passive layers such as a temperature compensation layer (FIG. 10A) or an interposer layer disposed between layers of piezoelectric material (FIG. 10B). Additionally, adjacent layers of piezoelectric material may have polarities that are inverted relative to one another (FIG. 10B).

The material layer stacks of BAW resonators operating at overtones may have various configurations. FIG. 11 illustrates the material layer stacks of a BAW resonator operating at the fundamental tone as compared to material layer stacks of BAW resonators operating at the first overtone, high odd modes, and high even modes in both detailed and simplified illustrations. The high odd mode configuration has a thicker interposer layer between the piezoelectric material layers than the high even mode configuration, and in the high odd mode configuration the piezoelectric material layers have the same polarity while in the high even mode configuration the piezoelectric material layers have opposite polarities.

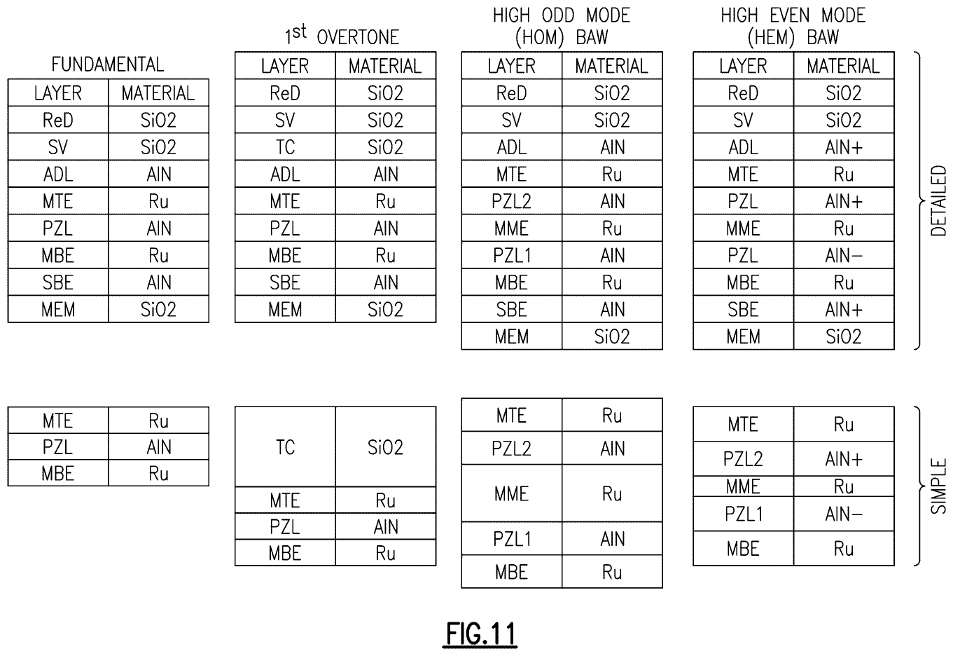

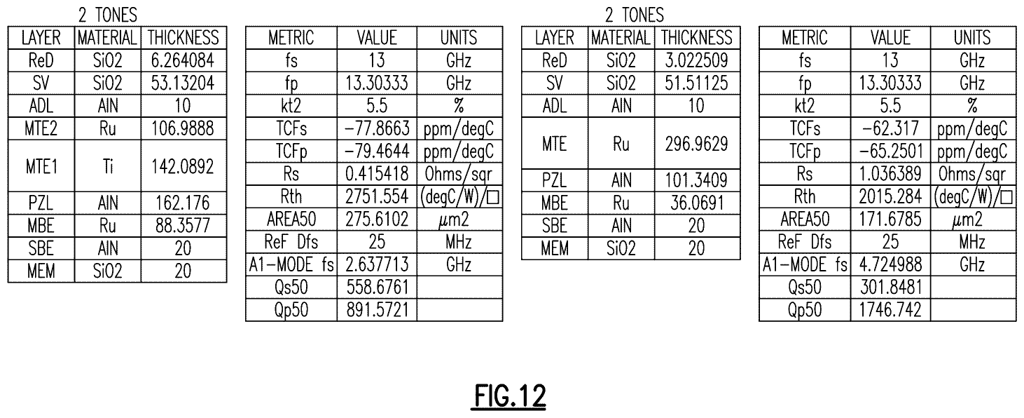

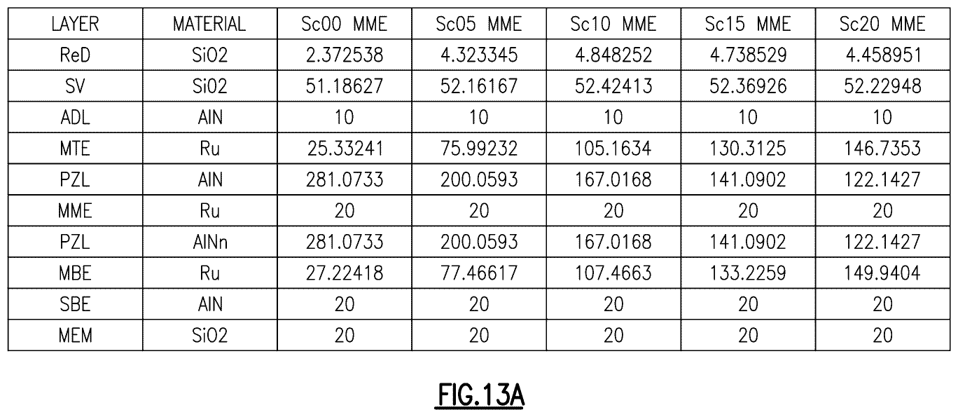

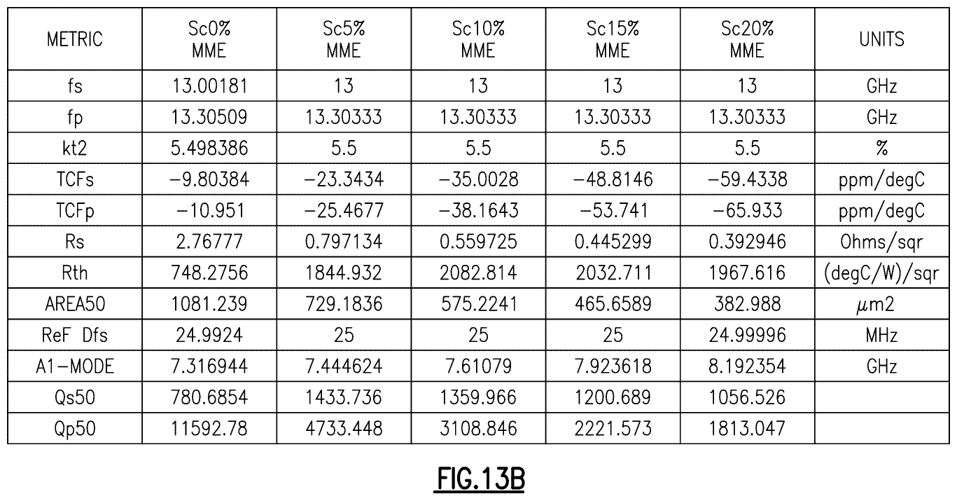

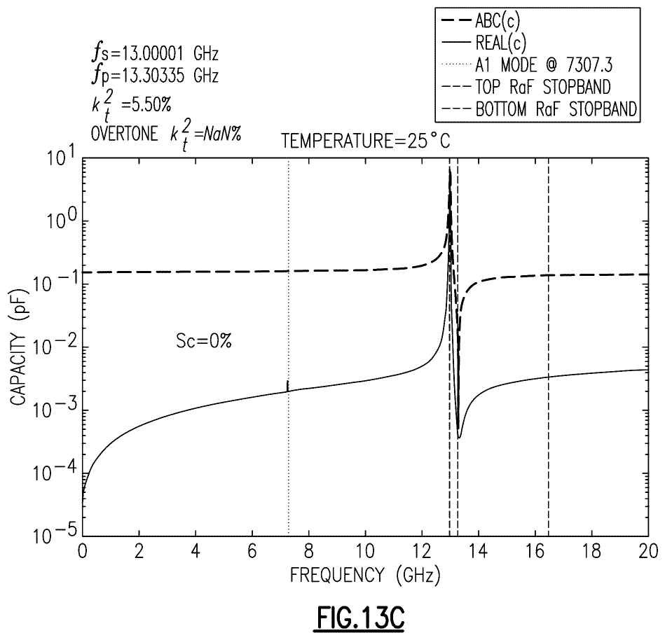

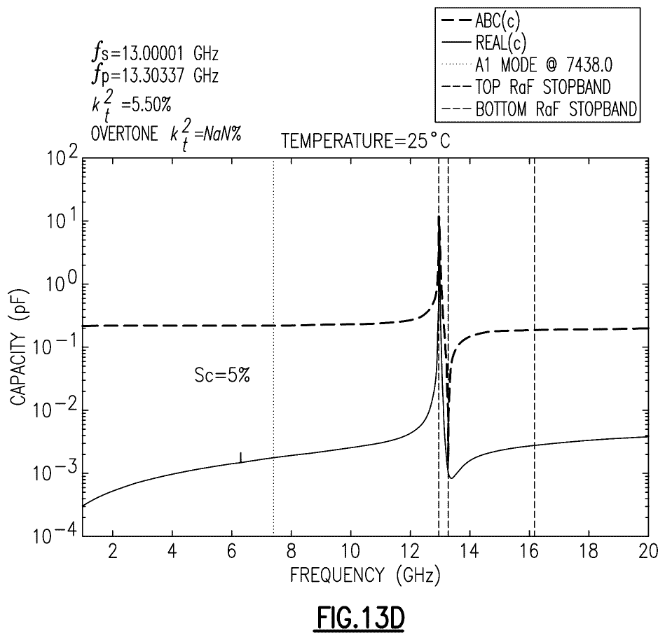

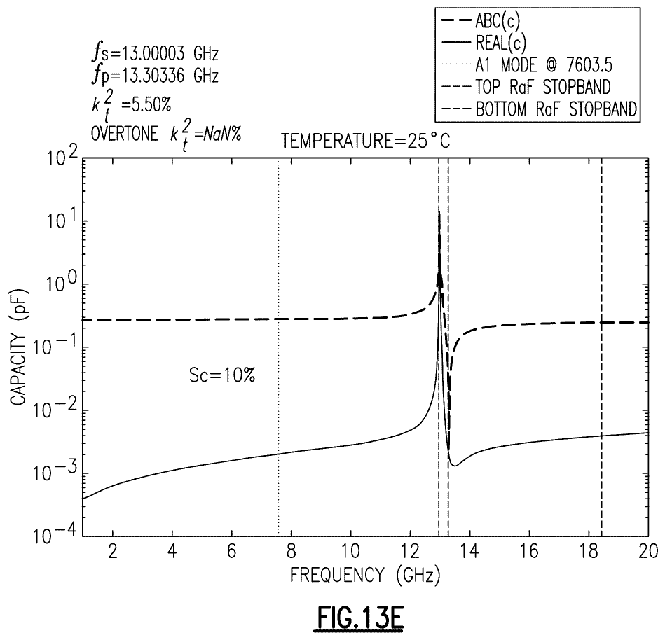

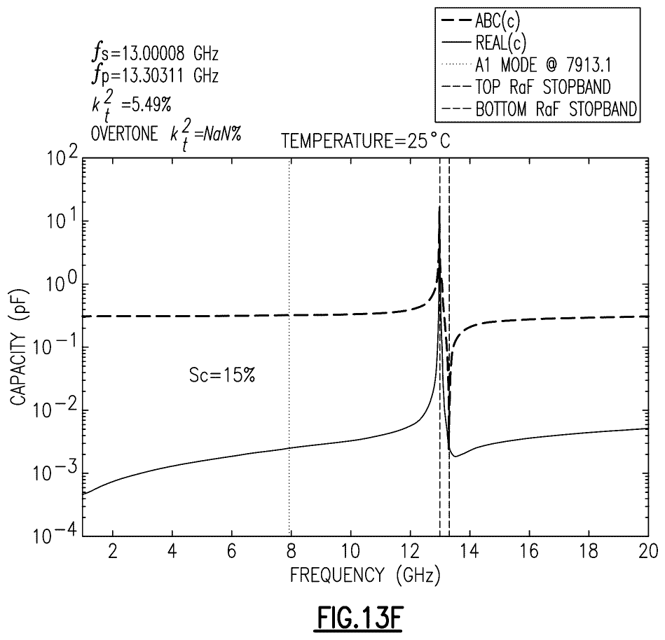

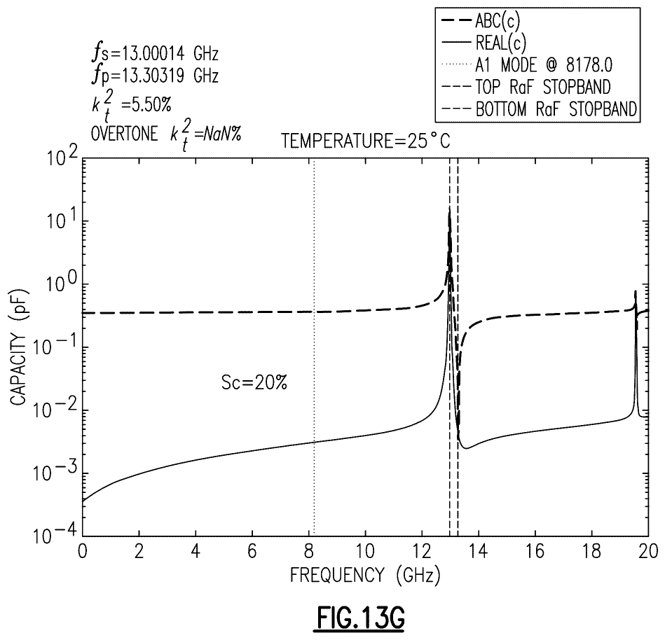

FIG. 12 compares material layer stacks of two BAW resonators operating at the first overtone and including passive layers and associated simulated performance metrics. In FIG. 12, the passive layers are the very thick MTE layers (MTE1/Ti in 1st table and MTE/Ru in 3rd table). Even though there is a single piezoelectric material layer in the material layer stacks shown in FIG. 12, the thickness of the top electrode causes an overtone mode to be generated. A first of the two material layer stacks includes a top electrode including both a layer of Ti and a layer of Ru while the second of the two material layer stacks includes a top electrode formed of Ru only. The Ti layer in the first of the two material layer stacks reduces the series resistance Rs of the material layer stack as compared to the Rs of the second of the two material layer stacks. FIG. 13A illustrates examples of material layer stacks for BAW resonators operating at the first overtone where the piezoelectric material layers are doped with different amounts of Sc: 0 atomic percent (Sc00), 5 atomic percent (Sc05), 10 atomic percent (Sc10), 15 atomic percent (Sc 15), and 20 atomic percent (Sc20). These percentages are atomic percentages. FIG. 13B illustrates simulated performance metrics for BAW resonators having the material layer stacks illustrated in FIG. 13A. From FIG. 13B it can be seen that as the amount of Sc doping increases, the Rs of the material layer stacks decrease, but the TCF becomes more negative. FIGS. 13C-13G illustrate simulated admittance curves for BAW resonators having the material layer stacks illustrated in FIG. 13A.

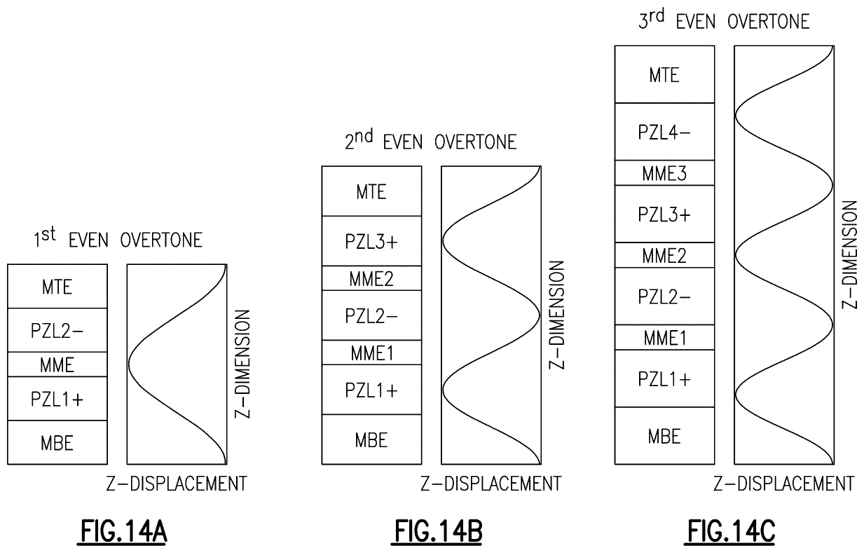

FIGS. 14A-14C illustrate what is meant by the term “high even overtone” resonators herein. A first even overtone mode resonator (FIG. 14A) has 1.0 longitudinal wavelengths within the material layer stack. A first even overtone mode resonator may also be referred to herein as a “Tone 2” resonator. A second even overtone mode resonator (FIG. 14B) has 2.0 longitudinal wavelengths within the material layer stack and may also be referred to herein as a “Tone 4” resonator. A third even overtone mode resonator (FIG. 14C) has 3.0 longitudinal wavelengths within the material layer stack and may also be referred to herein as a “Tone 6” resonator.

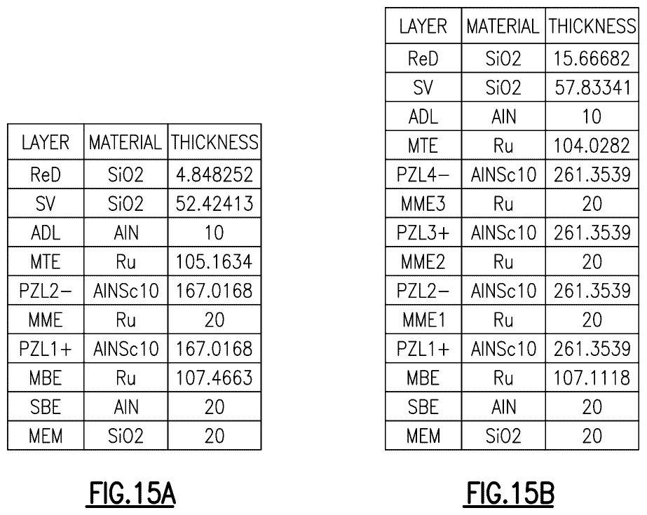

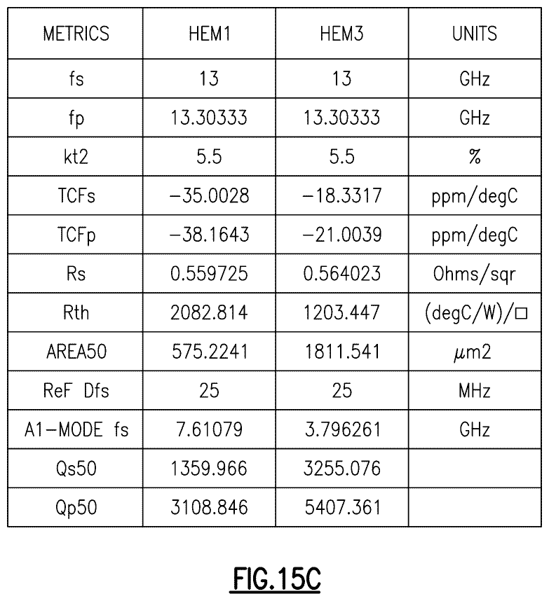

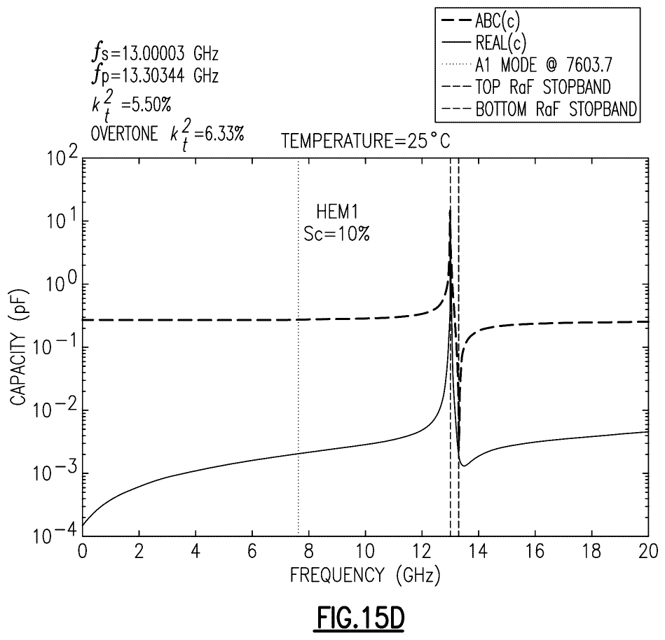

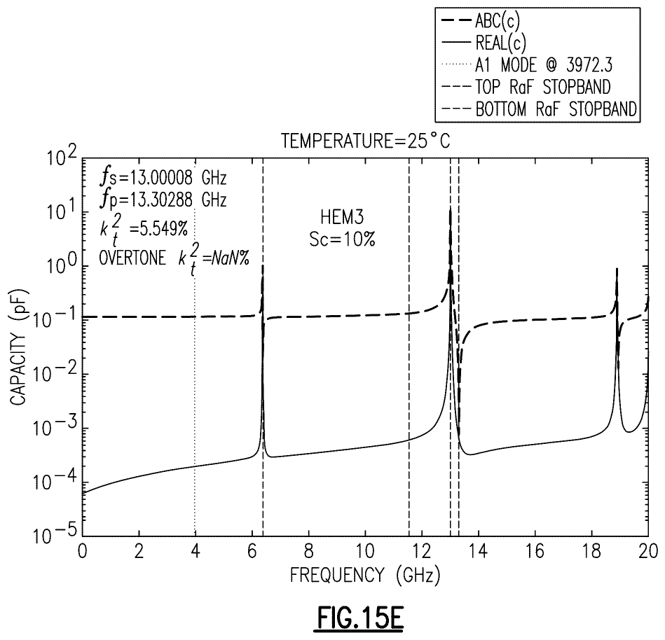

A comparison between examples of material layer stacks for a first even overtone mode resonator and a third even overtone mode resonator with piezoelectric material layers doped with 10 atomic percent Sc are illustrated in FIGS. 15A and 15B, respectively. Simulated performance metrics for these resonators are shown in FIG. 15C. It can be seen from FIG. 15C that as the order of the overtone of the resonator increases for a given operating frequency and given electromechanical coupling coefficient (kt2) the TCF of the resonator improves (becomes less negative) but the area of the resonator (Area50) increases. Simulated admittance curves for the first even overtone mode BAW resonator and the third even overtone mode BAW resonator are illustrated in FIGS. 15D and 15E, respectively.

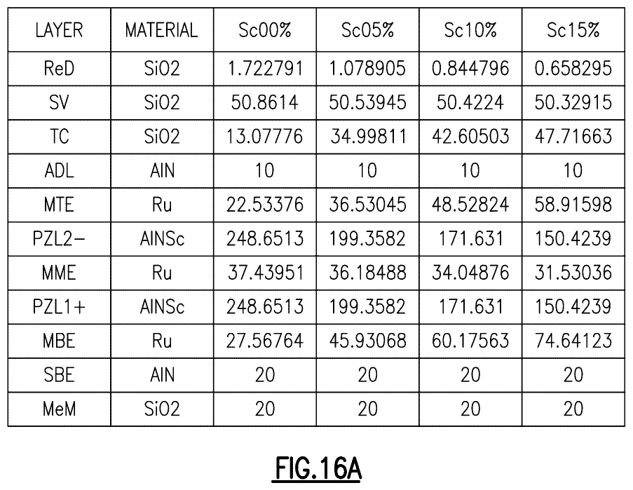

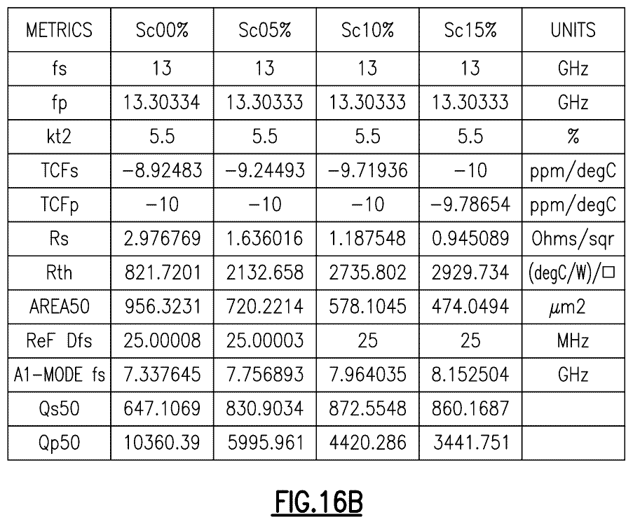

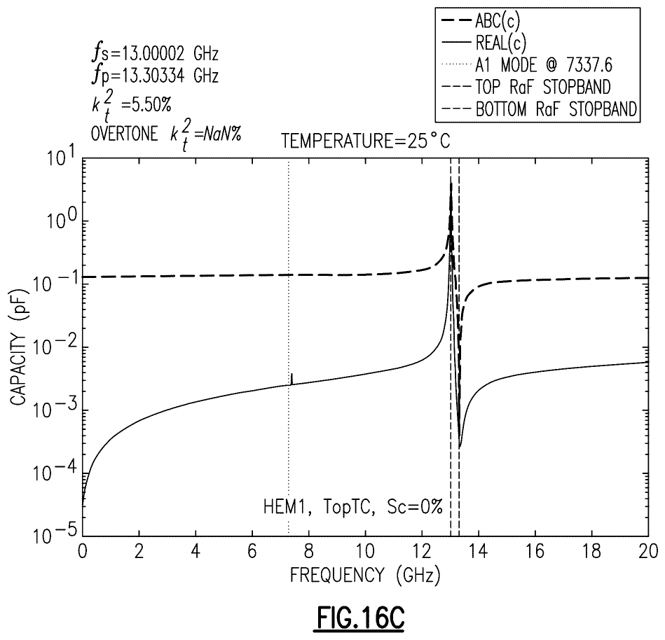

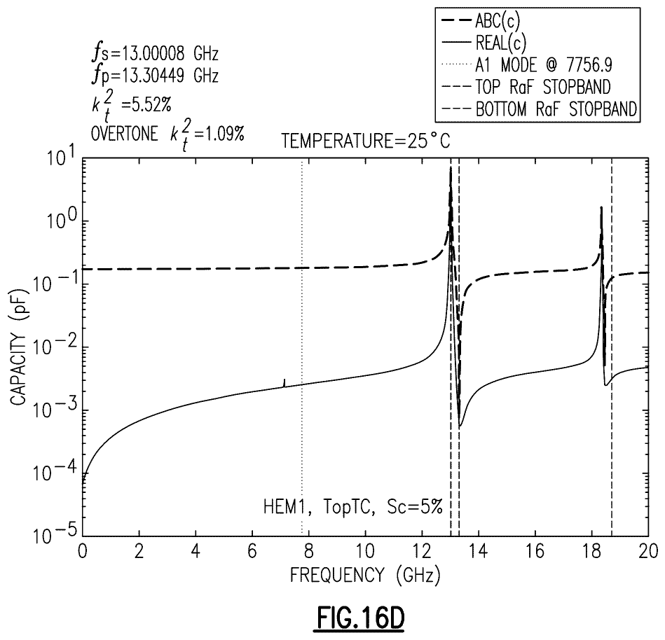

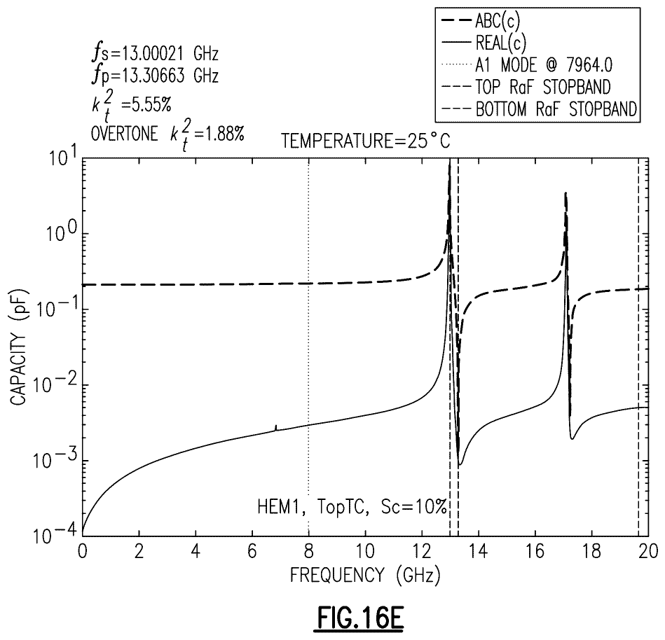

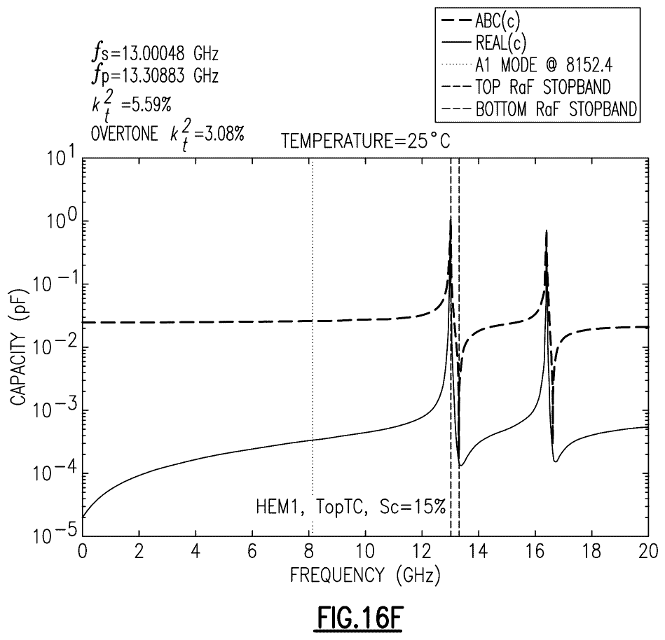

Examples of material layer stacks for first even overtone BAW resonators including a SiO₂ temperature compensation layer (TC) above the top electrode and varying amounts of Sc doping in the piezoelectric material layers are shown in FIG. 16A. Simulated performance metrics for BAW resonators having these material layer stacks are shown in FIG. 16B. Simulated admittance curves for BAW resonators having these material layer stacks are shown in FIGS. 16C-16F.

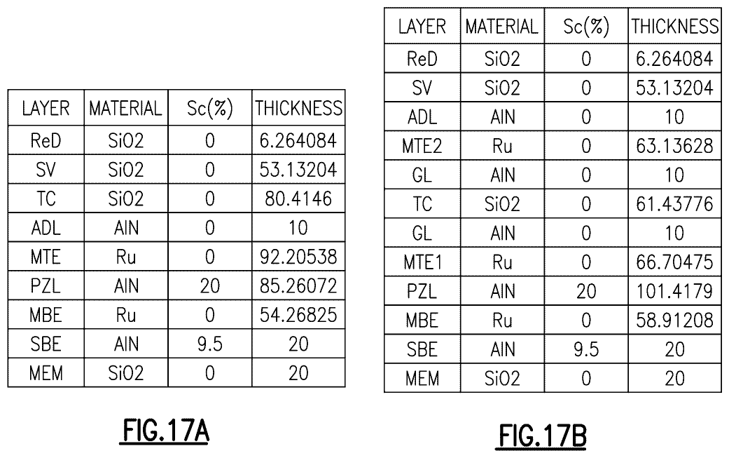

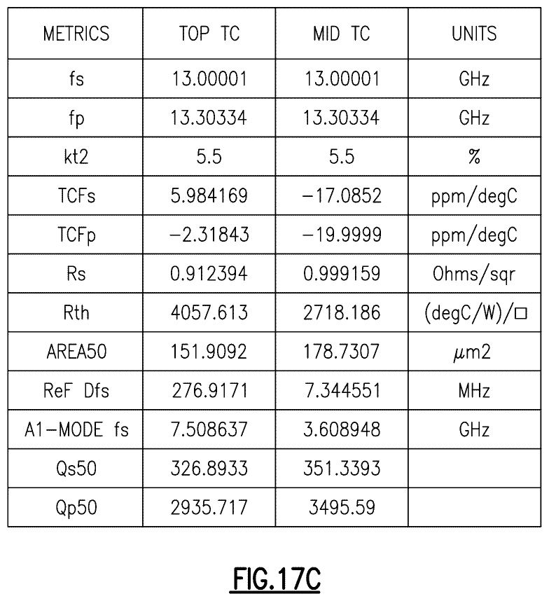

In other embodiments, the TC layer may be disposed between upper and lower top electrode layers. FIGS. 17A and 17B illustrate material layer stacks for first overtone BAW resonators each operating at 13 GHz with a TC layer above the top electrode (Top TC, FIG. 17A) or between upper and lower top electrode layers (Mid TC, FIG. 17B). Adhesion layers GL between the upper and lower top electrode layers in the Mid TC stack are indicated as being AlN, but could alternatively be formed of Al or Ti. FIG. 17C illustrates simulated performance parameters for BAW resonators having these material layer stacks. The thickness of the piezoelectric material layer in the Mid TC stack was greater than that of the Top TC stack, but at the cost of TCF (TCF parameters further from zero) and a slight increase in series resistance.

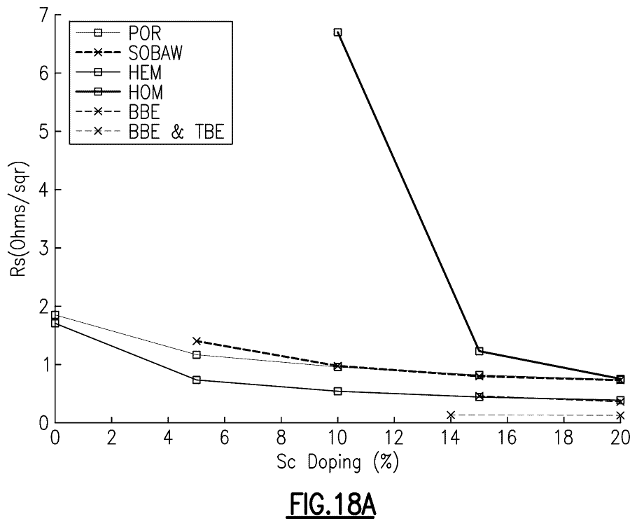

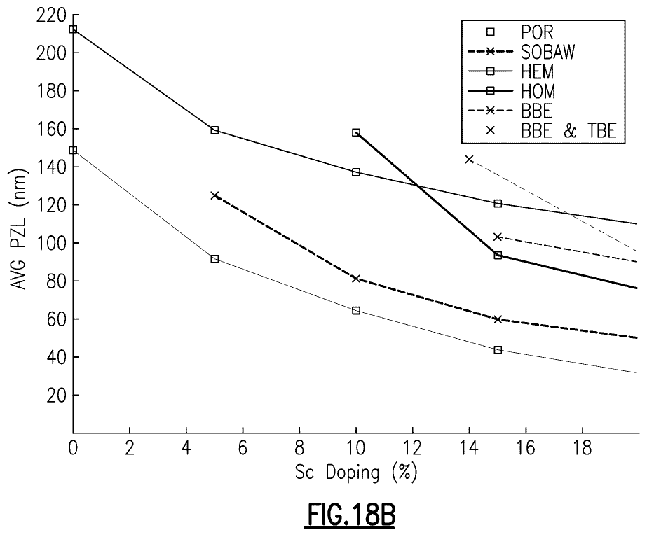

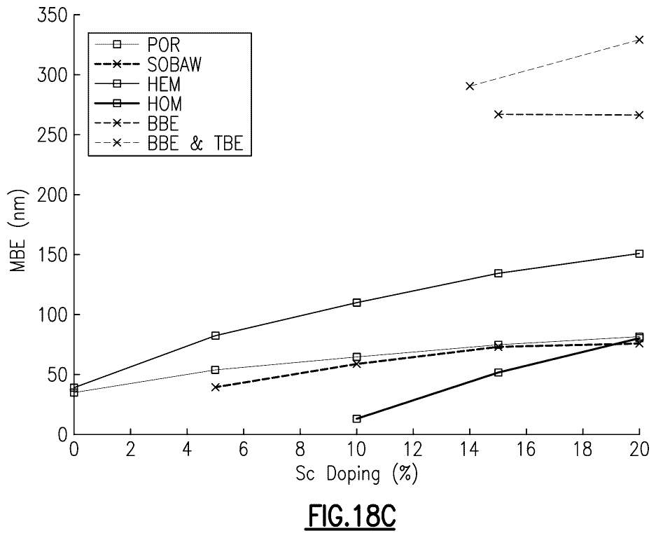

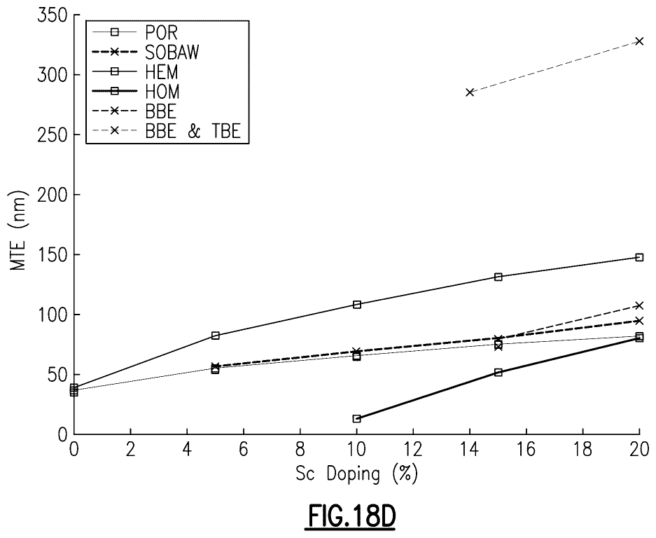

FIG. 18A is a comparison of simulated series resistance of BAW resonators operating at the fundamental mode (POR), a high even mode (HEM) (the first overtone), and a high odd mode (HOM) (the second overtone) at the same operating frequency (13 GHZ) and with varying Sc doping of the piezoelectric material layers. The series resistance for the HEM resonator was best (lowest) at all Sc doping levels.

FIG. 18B is a comparison of simulated average piezoelectric material layer thickness of BAW resonators operating at the fundamental mode, a high even mode, and a high odd mode at the same operating frequency and with varying Sc doping of the piezoelectric material layers. The average piezoelectric material layer thickness for the HEM resonator was best (greatest) at most Sc doping levels, although the HOM resonator had a greater piezoelectric material layer thickness at a Sc doping level of 10 atomic percent.

FIGS. 18C and 18D are comparisons of simulated bottom electrode and top electrode thicknesses of BAW resonators operating at the fundamental mode, a high even mode, and a high odd mode at the same operating frequency and with varying Sc doping of the piezoelectric material layers. The electrode thicknesses for the HEM resonator was best (greatest) at all Sc doping levels.

The acoustic wave devices discussed herein can be implemented in a variety of filters and packaged modules. Some example packaged modules will now be discussed in which any suitable principles and advantages of the packaged acoustic wave devices discussed herein can be implemented. FIGS. 19, 20, 21, and 22 are schematic block diagrams of an illustrative filter and packaged modules and devices according to certain embodiments.

As discussed above, embodiments of the disclosed BAW resonators can be configured as or used in filters, for example. In turn, a BAW filter using one or more BAW elements may be incorporated into and packaged as a module that may ultimately be used in an electronic device, such as a wireless communications device, for example.

In some embodiments, multiple BAW resonators as disclosed herein may be combined into a filter, for example, an RF ladder filter schematically illustrated in FIG. 19 and including a plurality of series resonators R1, R3, R5, R7, and R9, and a plurality of parallel (or shunt) resonators R2, R4, R6, and R8. As shown, the plurality of series resonators R1, R3, R5, R7, and R9 are connected in series between the input and the output of the RF ladder filter, and the plurality of parallel resonators R2, R4, R6, and R8 are respectively connected between series resonators and ground in a shunt configuration. Other filter structures and other circuit structures known in the art that may include BAW devices or resonators, for example, duplexers, baluns, etc., may also be formed including examples of BAW resonators as disclosed herein.

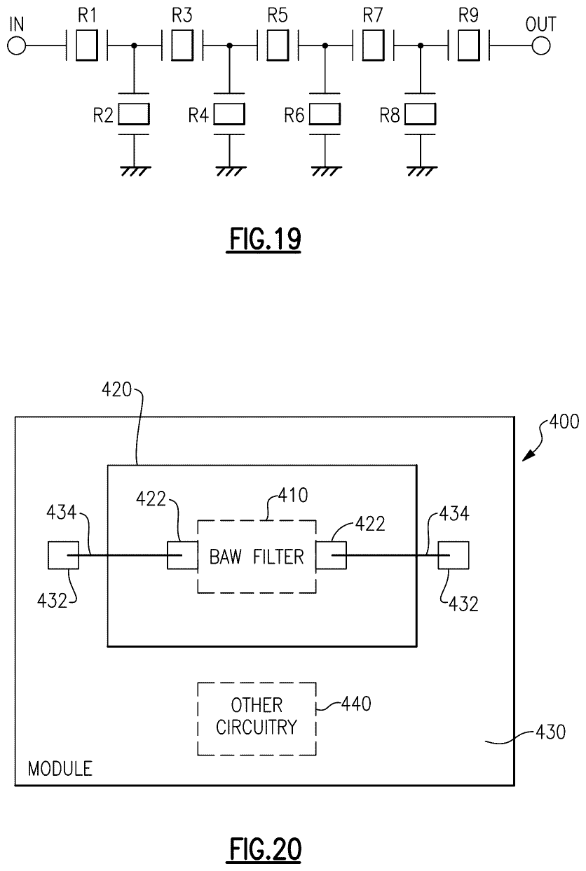

FIG. 20 is a block diagram illustrating one example of a module 400 including a BAW filter 410. The BAW filter 410 may be implemented on one or more die(s) 420 including one or more connection pads 422. For example, the BAW filter 410 may include a connection pad 422 that corresponds to an input contact for the BAW filter and another connection pad 422 that corresponds to an output contact for the BAW filter. The packaged module 400 includes a packaging substrate 430 that is configured to receive a plurality of components, including the die 420. A plurality of connection pads 432 can be disposed on the packaging substrate 430, and the various connection pads 422 of the BAW filter die 420 can be connected to the connection pads 432 on the packaging substrate 430 via electrical connectors 434, which can be solder bumps or wirebonds, for example, to allow for passing of various signals to and from the BAW filter 410. The module 400 may optionally further include other circuitry die 440, such as, for example, one or more additional filter(s), amplifiers, pre-filters, modulators, demodulators, down converters, and the like, as would be known to one of skill in the art of semiconductor fabrication in view of the disclosure herein. In some embodiments, the module 400 can also include one or more packaging structures to, for example, provide protection and facilitate easier handling of the module 400. Such a packaging structure can include an overmold formed over the packaging substrate 430 and dimensioned to substantially encapsulate the various circuits and components thereon.

Various examples and embodiments of the BAW filter 410 can be used in a wide variety of electronic devices. For example, the BAW filter 410 can be used in an antenna duplexer, which itself can be incorporated into a variety of electronic devices, such as RF front-end modules and communication devices.

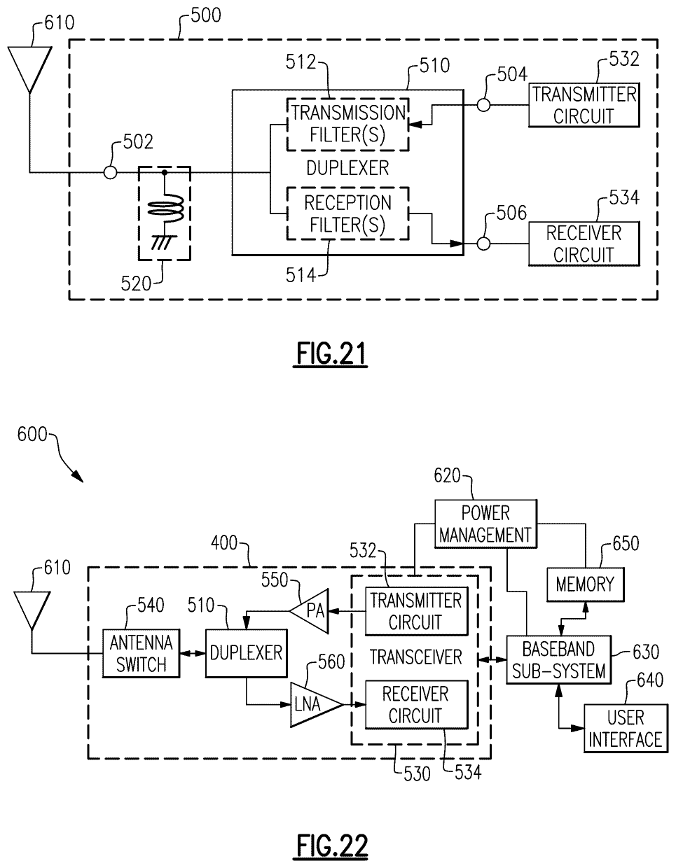

Referring to FIG. 21, there is illustrated a block diagram of one example of a front-end module 500, which may be used in an electronic device such as a wireless communications device (e.g., a mobile phone) for example. The front-end module 500 includes an antenna duplexer 510 having a common node 502, an input node 504, and an output node 506. An antenna 610 is connected to the common node 502.

The antenna duplexer 510 may include one or more transmission filters 512 connected between the input node 504 and the common node 502, and one or more reception filters 514 connected between the common node 502 and the output node 506. The passband(s) of the transmission filter(s) are different from the passband(s) of the reception filter(s). Examples of the BAW filter 410 can be used to form the transmission filter(s) 512 and/or the reception filter(s) 514. An inductor or other matching component 520 may be connected at the common node 502.

The front-end module 500 further includes a transmitter circuit 532 connected to the input node 504 of the duplexer 510 and a receiver circuit 534 connected to the output node 506 of the duplexer 510. The transmitter circuit 532 can generate signals for transmission via the antenna 610, and the receiver circuit 534 can receive and process signals received via the antenna 610. In some embodiments, the receiver and transmitter circuits are implemented as separate components, as shown in FIG. 21, however in other embodiments these components may be integrated into a common transceiver circuit or module. As will be appreciated by those skilled in the art, the front-end module 500 may include other components that are not illustrated in FIG. 21 including, but not limited to, switches, electromagnetic couplers, amplifiers, processors, and the like.

FIG. 22 is a block diagram of one example of a wireless device 600 including the antenna duplexer 510 shown in FIG. 21. The wireless device 600 can be a cellular phone, smart phone, tablet, modem, communication network or any other portable or non-portable device configured for voice or data communication. The wireless device 600 can receive and transmit signals from the antenna 610. The wireless device includes an embodiment of a front-end module 500 similar to that discussed above with reference to FIG. 21. The front-end module 500 includes the duplexer 510, as discussed above. In the example shown in FIG. 22 the front-end module 500 further includes an antenna switch 540, which can be configured to switch between different frequency bands or modes, such as transmit and receive modes, for example. In the example illustrated in FIG. 22, the antenna switch 540 is positioned between the duplexer 510 and the antenna 610; however, in other examples the duplexer 510 can be positioned between the antenna switch 540 and the antenna 610. In other examples the antenna switch 540 and the duplexer 510 can be integrated into a single component.

The front-end module 500 includes a transceiver 530 that is configured to generate signals for transmission or to process received signals. The transceiver 530 can include the transmitter circuit 532, which can be connected to the input node 504 of the duplexer 510, and the receiver circuit 534, which can be connected to the output node 506 of the duplexer 510, as shown in the example of FIG. 21.

Signals generated for transmission by the transmitter circuit 532 are received by a power amplifier (PA) module 550, which amplifies the generated signals from the transceiver 530. The power amplifier module 550 can include one or more power amplifiers. The power amplifier module 550 can be used to amplify a wide variety of RF or other frequency-band transmission signals. For example, the power amplifier module 550 can receive an enable signal that can be used to pulse the output of the power amplifier to aid in transmitting a wireless local area network (WLAN) signal or any other suitable pulsed signal. The power amplifier module 550 can be configured to amplify any of a variety of types of signal, including, for example, a Global System for Mobile (GSM) signal, a code division multiple access (CDMA) signal, a W-CDMA signal, a Long-Term Evolution (LTE) signal, or an EDGE signal. In certain embodiments, the power amplifier module 550 and associated components including switches and the like can be fabricated on gallium arsenide (GaAs) substrates using, for example, high-electron mobility transistors (pHEMT) or insulated-gate bipolar transistors (BiFET), or on a Silicon substrate using complementary metal-oxide semiconductor (CMOS) field effect transistors.

Still referring to FIG. 22, the front-end module 500 may further include a low noise amplifier module 560, which amplifies received signals from the antenna 610 and provides the amplified signals to the receiver circuit 534 of the transceiver 530.

The wireless device 600 of FIG. 22 further includes a power management sub-system 620 that is connected to the transceiver 530 and manages the power for the operation of the wireless device 600. The power management system 620 can also control the operation of a baseband sub-system 630 and various other components of the wireless device 600. The power management system 620 can include, or can be connected to, a battery (not shown) that supplies power for the various components of the wireless device 600. The power management system 620 can further include one or more processors or controllers that can control the transmission of signals, for example. In one embodiment, the baseband sub-system 630 is connected to a user interface 640 to facilitate various input and output of voice and/or data provided to and received from the user. The baseband sub-system 630 can also be connected to memory 650 that is configured to store data and/or instructions to facilitate the operation of the wireless device, and/or to provide storage of information for the user. Any of the embodiments described above can be implemented in association with mobile devices such as cellular handsets. The principles and advantages of the embodiments can be used for any systems or apparatus, such as any uplink wireless communication device, that could benefit from any of the embodiments described herein. The teachings herein are applicable to a variety of systems. Although this disclosure includes some example embodiments, the teachings described herein can be applied to a variety of structures. Any of the principles and advantages discussed herein can be implemented in association with RF circuits configured to process signals in a range from about 30 kHz to 300 GHz, such as in a range from about 450 MHz to 6 GHZ.

Aspects of this disclosure can be implemented in various electronic devices. Examples of the electronic devices can include, but are not limited to, consumer electronic products, parts of the consumer electronic products such as packaged radio frequency modules, uplink wireless communication devices, wireless communication infrastructure, electronic test equipment, etc. Examples of the electronic devices can include, but are not limited to, a mobile phone such as a smart phone, a wearable computing device such as a smart watch or an ear piece, a telephone, a television, a computer monitor, a computer, a modem, a hand-held computer, a laptop computer, a tablet computer, a microwave, a refrigerator, a vehicular electronics system such as an automotive electronics system, a stereo system, a digital music player, a radio, a camera such as a digital camera, a portable memory chip, a washer, a dryer, a washer/dryer, a copier, a facsimile machine, a scanner, a multi-functional peripheral device, a wrist watch, a clock, etc. Further, the electronic devices can include unfinished products.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled,” as generally used herein, refers to two or more elements that may be either directly connected, or connected by way of one or more intermediate elements. Likewise, the word “connected,” as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding, with or without author input or prompting, whether these features, elements and/or states are included or are to be performed in any particular embodiment.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while blocks are presented in a given arrangement, alternative embodiments May perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. The accompanying claims and their equivalents are intended to cover such forms or modifications as would fall within the scope and spirit of the disclosure.

1. A bulk acoustic wave resonator including a material layer stack located in a central active region of the bulk acoustic wave resonator, the material layer stack comprising:
a bottom electrode;
a first piezoelectric material layer disposed on an upper surface of the bottom electrode;
a second piezoelectric material layer disposed on the first piezoelectric material layer, a polarity of the second piezoelectric material layer being opposite a polarity of the first piezoelectric material layer;
an interposer layer disposed between the first piezoelectric material layer and the second piezoelectric material layer; and
a top electrode having a lower surface disposed on an upper surface of the second piezoelectric material layer.

2. The bulk acoustic wave resonator of claim 1 wherein the interposer layer is formed of ruthenium.

3. The bulk acoustic wave resonator of claim 1 wherein the interposer layer has a thickness sufficient to cause the bulk acoustic wave resonator to generate a second overtone vibrational mode.

4. The bulk acoustic wave resonator of claim 1 further comprising a third piezoelectric material layer disposed between the second piezoelectric material layer and the top electrode.

5. The bulk acoustic wave resonator of claim 4 wherein the third piezoelectric material layer has a polarity opposite to the polarity of the second piezoelectric material layer.

6. The bulk acoustic wave resonator of claim 5 further comprising a second interposer layer disposed between the second piezoelectric material layer and the third piezoelectric material layer.

7. The bulk acoustic wave resonator of claim 5 wherein at least one of the first, second, or third piezoelectric material layers has a different thickness than at least one other of the first, second, or third piezoelectric material layers.

8. The bulk acoustic wave resonator of claim 7 wherein the second piezoelectric material layer is thicker than the first piezoelectric material layer and the third piezoelectric material layer.

9. The bulk acoustic wave resonator of claim 6 further comprising a fourth piezoelectric material layer disposed between the third piezoelectric material layer and the top electrode.

10. The bulk acoustic wave resonator of claim 9 wherein the fourth piezoelectric material layer has a polarity opposite to the polarity of the third piezoelectric material layer.

11. The bulk acoustic wave resonator of claim 10 further comprising a third interposer layer disposed between the third piezoelectric material layer and the fourth piezoelectric material layer.

12. The bulk acoustic wave resonator of claim 1 further comprising a temperature compensation layer disposed over the top electrode, the temperature compensation layer having a thickness sufficient to cause the bulk acoustic wave resonator to generate a second overtone vibrational mode.

13. The bulk acoustic wave resonator of claim 1 wherein one of the bottom electrode or the top electrode has a thickness sufficient to cause the bulk acoustic wave resonator to generate a second overtone vibrational mode.

14. The bulk acoustic wave resonator of claim 1 wherein the first piezoelectric material layer and the second piezoelectric material layer are each Sc-doped AlN.

15. The bulk acoustic wave resonator of claim 14 wherein the first piezoelectric material layer and the second piezoelectric material layer include at least 15 atomic percent Sc.

16. The bulk acoustic wave resonator of claim 1 wherein the top electrode includes an upper layer, a lower layer, and a temperature compensation layer disposed between the upper layer and the lower layer.

17. The bulk acoustic wave resonator of claim 1 configured as a film bulk acoustic wave resonator.

18. A radio frequency filter including the bulk acoustic wave resonator of claim 1.

19. A radio frequency module including the radio frequency filter of claim 18.

20. A radio frequency device including the radio frequency module of claim 19.
